(19) United States
(12) Patent Application Publication
(10) Pub. No.: US 2025/0335154 A1
(43) Pub. Date: Oct. 30, 2025

(54) ANALOG COMPUTATION OF SHIFT AND ADD FOR DOT PRODUCT ENGINES

(71) Applicant: Hewlett Packard Enterprise Development LP, Spring, TX (US)

(72) Inventors: Luca Buonanno, Milpitas, CA (US); Lei Zhao, Ft. Collins, CO (US); Giacomo Pedretti, San Francisco, CA (US)

(21) Appl. No.: 18/651,338

(22) Filed: Apr. 30, 2024

(51) Int. Cl. G06F 7/506; G11C 13/00; G11C 15/04; G11C 27/00

(52) U.S. Cl. CPC G06F 7/506; G11C 13/0002; G11C 15/046; G11C 27/005

(57) ABSTRACT

In an example implementation, a circuit includes a dot product engine and a buffer circuit comprising a plurality of current buffers. Each current buffer has an input coupled to an associated output of the dot product engine. An integrator circuit is coupled to receive outputs of the current buffers. The buffer circuit can be configured to combine multiple currents for weight slicing.

### BACKGROUND

Dot product engines (DPEs) are circuits that enable the execution of matrix vector multiplications in the analog domain. This is achieved by encoding matrix entries into the conductance of a memory device. Matrix vector multiplication is a core operation in various computing intensive workloads, including neural networks. The precision of these operations is often limited by the precision of the input and the memristor, a type of memory device used in DPEs. To implement computations of higher precision, such as 8-bit computations with 4-bit memristors, a slicing operation is typically performed on the inputs and/or in the memristor array. This slicing operation often involves a ‘shift and add’ operation, which is traditionally performed in the digital domain. However, performing this operation in the digital domain can be costly and limit the performance of the accelerator.

### BRIEF DESCRIPTION OF THE DRAWINGS

For a more complete understanding of this disclosure, and advantages thereof, reference is now made to the following descriptions taken in conjunction with the accompanying drawings, in which:

FIG. 1 illustrates an example implementation of a system that includes a dot product engine and an integration circuit;

FIG. 2 illustrates a diagram of a dot product engine according to example implementations;

FIG. 3 illustrates circuit with an integrator using an add and chop technique, according to an example implementation;

FIG. 4 illustrates a timing diagram related to the operation of the circuit shown in FIG. 3, according to an example implementation;

FIG. 5 illustrates a flow chart of a method of performing an analog computation, according to an example implementation;

FIG. 6 illustrates a circuit using current buffers for bit slicing, according to an example implementation;

FIG. 7 illustrates a timing diagram for the operation of the example shown in FIG. 6, according to an example implementation;

FIG. 8 illustrates a circuit using a current buffer for bit slicing, according to an example implementation;

FIG. 9 illustrates a timing diagram for the operation of the example shown in FIG. 8, according to an example implementation;

FIG. 10 illustrates a flow chart of a method of performing an analog computation, according to an example implementation; and

FIG. 11 illustrates an example of an implementation of any of the examples disclosed herein.

### DESCRIPTION

The following disclosure provides many different examples for implementing different features. Specific examples of components and arrangements are described below to simplify the present disclosure. These are merely examples and are not intended to be limiting and may be used in combination.

The present disclosure pertains to the field of analog domain computations, such as on operations performed using dot product engines (DPEs). DPEs are specialized circuits that facilitate the execution of matrix vector multiplications in the analog domain. This is accomplished by encoding matrix entries into the conductance of a memory device, a process that forms the backbone of various computing intensive workloads, including neural networks. However, the precision of these operations is often constrained by the precision of the input and the memristor, a type of memory device used in DPEs.

To overcome this limitation and implement computations of higher precision, a slicing operation can be performed on the inputs and/or in the memristor array. This slicing operation often involves a ‘shift and add’ operation, which is traditionally performed in the digital domain. However, performing this operation in the digital domain can be costly and limit the performance of the accelerator.

The present disclosure introduces implementations in the analog domain for the ‘shift and add’ operation. These implementations are designed to increase the precision of the algebraic operation when the inputs or the weights of a DPE are sliced. A first example implementation involves the use of two paired capacitances to divide the integrated charge, which is the DPE output, by a fixed amount. This operation corresponds to a bit shift if the ratio is properly designed. A second example implementation employs a programmable ratio between transistors to divide the current signal conveyed after the DPE by a fixed amount. If the mirroring ratios are designed properly, this stage performs a bit shift of the analog signal.

These methods offer potential advantages in terms of accuracy and efficiency. The use of capacitance matching in the first method can provide good accuracy at scaled nodes, and the use of switching capacitors enables short transient times, leading to a high frequency of operation. The second method, on the other hand, allows for the combination of multiple currents for weight slicing with a relatively small area overhead, with the use of current mirrors. These implementations, therefore, present potential solutions to the challenges of performing ‘shift and add’ operations in the analog domain, thereby enhancing the performance and precision of DPEs.

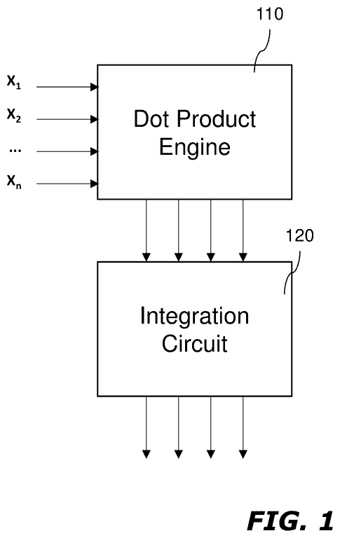

FIG. 1 illustrates an example implementation of a system that can utilize concepts discussed herein. This simplified example illustrates a dot product engine 110 that receives inputs x₁-xₙ and outputs a dot product based on elements programmed in the dot product engine 110. This resultant product can be provided to an integration circuit 120 as will be discussed in greater detail herein.

The dot product engine (DPE) 110 is a specialized hardware component designed to perform dot product operations efficiently. Dot products are fundamental operations in linear algebra and are widely used in various applications, including machine learning, signal processing, and computer graphics.

The dot product engine 110 is designed to exploit parallelism and pipelining techniques to achieve high throughput and low latency. It may also incorporate additional features such as precision control, saturation arithmetic, and support for various data formats. By offloading the computationally intensive dot product operations to dedicated hardware, the dot product engine can significantly accelerate applications that heavily rely on these operations, such as neural network inference and matrix operations.

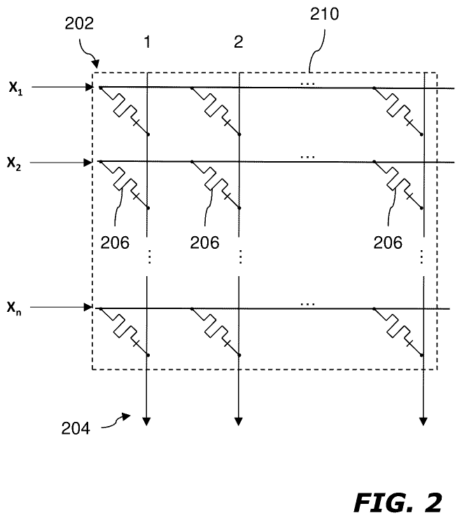

FIG. 2 is a diagram of a dot product engine 210 that can serve as a programmable crossbar array, according to some implementations. This figure is intended to be illustrative with the understanding that other technologies can be substituted. The dot product engine 210 includes a plurality of input electrodes 202, a plurality of output electrodes 204, and plurality of programmable elements 206. The input electrodes 202 are arranged in rows to receive inputs x₁-xₙ and the output electrodes 204 are arranged in columns. Each programmable element 206 is positioned at a crosspoint or junction of an input electrode 202 and an output electrode 204. As input, the dot product engine 210 takes a vector of analog signals (on the input electrodes 202).

The programmable elements 206 are circuit elements whose conductance is programmable. The programmable elements 206 are non-volatile analog devices, which may be adapted to store multiple bits of data. An example of a programmable element is a memristor, which includes a dielectric layer (e.g., an oxide layer) between two metal layers. When the programmable elements 206 are memristors, the dot product engine 210 is a memristor array. Other examples of programmable elements include multi-bit flash memory cells, resistive random-access memory (ReRAM) cells, phase-change random-access memory (PCRAM) cells, magnetoresistive random-access memory (MRAM) cells, electrochemical random-access memory (ECRAM) cells, and the like.

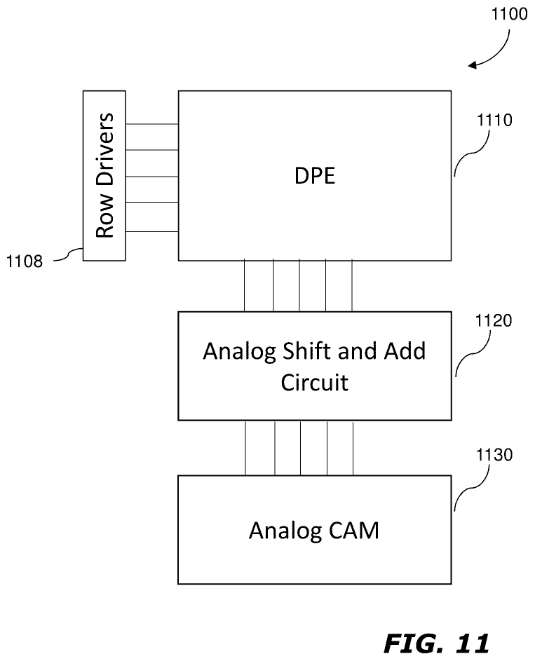

The dot product engine 210 may also include other peripheral circuitry (not separately illustrated). For example, the dot product engine 210 may include drivers connected to the input electrodes 202 (see e.g., FIG. 11). An address decoder can be used to select an input electrode 202 and activate a driver corresponding to the selected input electrode 202. The driver for a selected input electrode 202 can drive a corresponding input electrode 202 with different voltages corresponding to a vector-matrix multiplication or the process of setting resistance values within the programmable elements 206 of the dot product engine 210.

Control circuitry may also be used to control application of voltages at the inputs of the dot product engine 210. Input signals to the input electrodes 202 and the output electrodes 204 are analog signals. The peripheral circuitry above described can be fabricated using semiconductor processing techniques in the same integrated structure or semiconductor die as the dot product engine 210 as well as other circuitry such as integration circuit 120 and analog content address memory (as will be discussed with respect to FIG. 11).

The programmable elements 206 in the programmable dot product engine 210 are programmed so as to map the mathematic values in an N×M matrix to the programmable elements 206. During operation, a dot product or vector-matrix multiplication operation can be performed. In this operation, input voltages x₁-xₙ are applied to the input electrodes 202 and output currents are obtained from the output electrodes 204, corresponding to the result of multiplying an N×1 vector with the N×M matrixes. The input voltages are below the threshold of the programming voltage of the programmable elements 206 so the resistance values of the programmable elements in the dot product engine 210 are not changed during the vector-matrix multiplication operation.

A vector-matrix multiplication may be executed through the dot product engine 210 by applying a set of voltages simultaneously along the input electrodes 202 of the dot product engine 210 and collecting the currents through the output electrodes 204. The signal generated on an output electrode 204 is weighted by the corresponding conductance of the programmable elements 206 at the crosspoints of the output electrode 204 with the input electrodes 202, and that weighted summation is reflected in the current at the output electrode 204. Thus, the relationship between the voltages at the input electrodes 202 and the currents at the output electrodes 204 is represented by a vector-matrix multiplication of the input vector with the N×M matrix determined by the conductances of the programmable elements 206 for the query dot product engine 210.

The dot product engine 110 can employ several techniques to handle large inputs and weights efficiently. The input slicing technique involves feeding the input vectors sequentially to the dot product engine 110, with each input having a different level of significance. The inputs are partitioned into slices based on their significance, and the dot product engine 110 processes these slices one after another. The resulting outputs are then combined while keeping track of the corresponding significance for each output in the sequence.

Another technique is weight slicing, which is particularly useful when dealing with large weight matrices or kernels. In this approach, the weight matrix is divided into multiple columns or slices, where each column represents a different significant part of the overall weight. These weight slices are written into different columns of the dot product engine's weight storage. During computation, the dot product engine 110 calculates the results for each weight slice, and these partial results are then combined by weighting each column's output with the correct significance level corresponding to that weight slice.

The input slicing and weight slicing techniques can be combined in the dot product engine's implementation. This allows handling scenarios where both the input vectors and weight matrices are too large to process directly. By employing a combination of these techniques, the dot product engine 110 can efficiently handle computations involving large-scale inputs and weights, breaking them down into manageable slices and recombining the results while preserving the appropriate significance levels.

Although this disclosure describes or illustrates particular operations as occurring in a particular order, this disclosure contemplates the operations occurring in any suitable order. Moreover, this disclosure contemplates any suitable operations being repeated one or more times in any suitable order. Although this disclosure describes or illustrates particular operations as occurring in sequence, this disclosure contemplates any suitable operations occurring at substantially the same time, where appropriate. Any suitable operation or sequence of operations described or illustrated herein may be interrupted, suspended, or otherwise controlled by another process, such as an operating system or kernel, where appropriate. The acts can operate in an operating system environment or as stand-alone routines occupying all or a substantial part of the system processing.

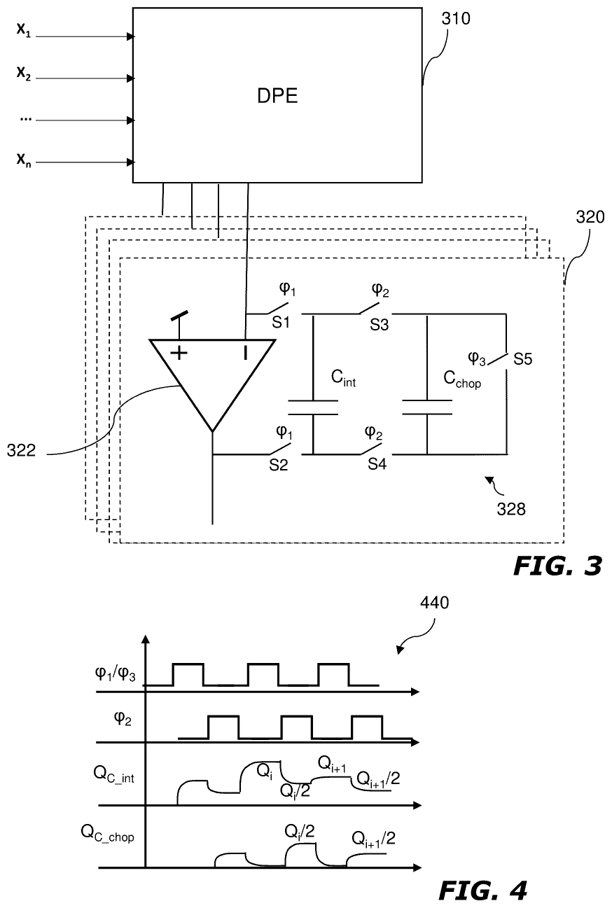

FIGS. 3-8 will be used to illustrate examples of integration circuit 120. In these examples, the precision of the dot product can be increased using input and weight slicing.

FIG. 3 illustrates an example of a dot product engine 310 that provides outputs to an integration circuit 320 to implement a chop and add technique. The integration circuit 320 may include an integrator.

As shown, the integration circuit 320 includes an operational amplifier 322 and a feedback capacitor 328 coupled to perform mathematical integration on an input voltage signal from the dot product engine 310. The op-amp is connected in a negative feedback loop, where the output is fed back to the inverting input through feedback capacitor 328. The non-inverting input is typically grounded or connected to another reference voltage. When an input voltage is applied to the inverting terminal, the capacitor charges or discharges proportionally to the integral of the input voltage over time. This results in an output voltage from the op-amp that represents the integrated value of the input signal. The integration constant is determined by the capacitance value and a feedback resistor (if present).

In the implementation of FIG. 3, the feedback capacitor 328 is implemented with a capacitance circuit 328. The capacitance circuit 328 includes two parallel capacitors, namely an integration capacitor Cᵢₙₜ and a chop capacitor C_{chop}, along with switches S1, S2, S3, S4, and S5. The switches S1 and S2 may be controlled by a first control signal φ₁, the switches S3 and S4 may be controlled by a second control signal φ₂, and switch S5 may be controlled by a third control signal φ₃. These control signals can be provided by a control circuit, which is not illustrated here.

The output values of the dot product engine 310 can be encoded by the charge integrated by the integration circuit 320 and the division operation can be performed as charge sharing with a nearby capacitance. After each division operation, the chop capacitor C_{chop} may be reset, and the integration circuit 320 can iteratively perform a new addition and a new division of the result of the addition. In this manner, the integration capacitor and the chop capacitor can share charge in a manner that corresponds to a bit shift operation.

In some aspects, the charge integrated on the last step corresponds to the most added amount. This amount of charge does not undergo a bit shift to the left. The charge integrated on the first step corresponds to the least added amount. This amount of charge undergoes multiple bit shifts to the left, as many shifts as the number of times the integration capacitor Cᵢₙₜ and the chop capacitor C_{chop} share the charge. For the various capacitance circuit, each chop capacitor C_{chop} may be dimensioned as follows: C_{chop}=Cᵢₙₜ·(2^{Nbitshift}−1), where N_{bitshift} represents a bit position of that integrator.

FIG. 4 illustrates a timing diagram 440 that shows the timing relationship between the first and second control signals φ₁, φ₂ and φ₃. These signals may be set up so that at any given time, one is high while the other is low. A high signal may open the respective switch S, such as switches S1, S2, S3, S4, and S5 as shown in FIG. 3.

In this implementation, the switches S1, S2, and S5 are controlled by the first and third controls signal φ₁ and φ₃, while the switches S3 and S4 are controlled by the second control signal φ₂. This arrangement may ensure that the switches are not simultaneously open, thereby controlling the flow of charge between the integration capacitor Cᵢₙₜ and the chop capacitor C_{chop}. It is understood, of course, that active low switches could alternatively be used. In other aspects, the switches S1, S2, S5 could be of opposite conductivity as switches S3 and S4.

The timing diagram 440 also illustrates the accumulation of charge Q_{C_int} of integration capacitor Cᵢₙₜ and charge Q_{C_chop} on chop capacitor C_{chop}. When the first control signal φ₁ closes switches S1, S2, charge capacitor Cᵢₙₜ is charged by amplifier 322. At the same time, the chop capacitor C_{chop} is isolated from the integration capacitor by having switches S3 and S4 opened by control signal φ₂ and the chop capacitor C_{chop} is reset by having switch S5 close by control signal φ₁. As shown, the charge Q_{C_chop} goes to zero at this time.

This process is repeated over time until the final accumulation is reached. This result provides an analog version of the dot product for each output of the integration circuit 320. Upon completion of the operation, the capacitors Cᵢₙₜ and C_{chop} can both be reset by closing switches S3, S4, and S5 while leaving switches S1 and S2 open.

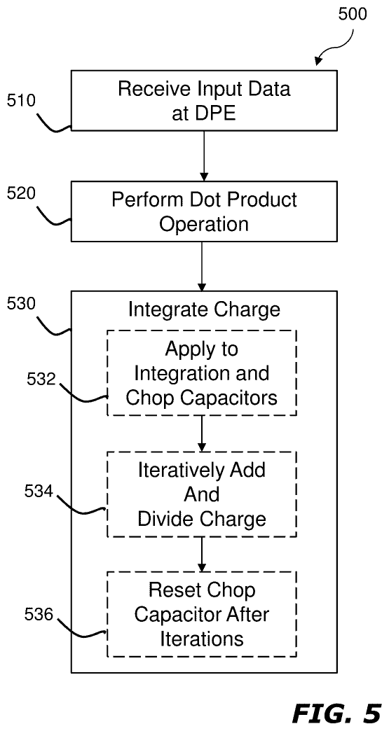

An example implementation of a method of performing an analog computation is illustrated in the flow chart 500 of FIG. 5. This method can be performed, for example, by the circuit of FIG. 3. Input data is received at a dot product engine in operation 510, a dot product operation is performed within the dot product engine in operation 520, and charge output from the dot product engine is integrated in operation 530.

In this example, the integration is performed using an integration capacitor and a chop capacitor (operation 532). The integrating is performed by iteratively adding and dividing charge to accumulate a result corresponding to the dot product of the input data and matrix entries encoded in the dot product engine (operation 534). The chop capacitor is reset for each iteration (operation 536).

In one example implementation, integrating the charge comprises operating a set of switches connected to the integration capacitor and the chop capacitor, e.g., as illustrated in FIG. 3. The switches can be controlled by control signals to implement charge sharing between the capacitors.

In one example implementation, integrating the charge comprises integrating the charge output from the dot product engine with a plurality of integrators each of which includes a respective integration capacitor and chop capacitor. The integration capacitor or chop capacitor of each integrator are weighted so that a result of the integrating corresponds to a bit shift operation.

FIG. 6 illustrates a second example implementation. This example uses current buffers 624 (i.e., 624-1 . . . 624-n) for bit slicing, such as for input slicing. Dot product engine 610 outputs integration stage input currents I1, I2, . . . In. Each of these currents I is provided to a respective one of the current buffers 624-1, 624-2, . . . 624-n. Each current buffer 624 may provide an input to a respective integrator, which is formed by an amplifier 622 (i.e., 622-1 . . . 622-n) having a capacitor C (i.e., C₁ . . . Cₙ) coupled between its input and output. The other input of each amplifier 622 is grounded.

Each current buffer 624 is a circuit designed to provide an output current that is proportional to the input current while maintaining a high output impedance. As such, the buffer can isolate the dot product engine 610 from the integrator, ensuring that the integrator load does not affect the operation of the dot product engine source.

In one example, each current buffer 624 can be implemented using CMOS technology. For example, the current buffer 624 can be designed using an operational amplifier with a feedback loop that enables it to maintain a constant current output regardless of the load impedance. The non-inverting input of the op-amp is connected to a reference voltage, while the inverting input is connected to a sensing resistor in series with the load. The op-amp adjusts its output voltage to maintain the voltage drop across the sensing resistor equal to the reference voltage, thereby ensuring a constant current through the load. The high input impedance and low output impedance of the operational amplifier allow it to drive a wide range of load impedances without affecting the current accuracy. While other technologies (e.g., bipolar) can be used, the CMOS implementation of the op-amp provides low power consumption and good integration with other CMOS circuits on the same chip.

In an example implementation, the output values of the dot product engine 610 are encoded by the charge integrated by the integration circuit 620 and the division operation is performed with a current buffer 624 that has a mirroring ratio. This ratio between transistors in the current buffer 624 may be used to divide the current signal conveyed after the dot product engine 610 by a fixed amount. This operation may correspond to a bit shift if the mirroring ratios are designed properly. In one example implementation, the mirroring ratio is fixed for each current butter. In other example, the mirroring ratio can be programmable to provide flexibility in various implementations.

Each time there is a current pulse to convey towards the integration circuit 620, the mirroring factor may define the magnitude of the charge packet, which in turn may be defined by the applied input, weighted by the memristor matrix. This use of current mirrors in the current buffer 624 may allow for the combination of multiple currents for weight slicing with a relatively small area overhead.

In some embodiments, successive integrate inputs can be summed in the integrator stage, each one representing a different part of the input signal. This may allow for a more precise and efficient ‘shift and add’ operation in the analog domain, thereby enhancing the performance and precision of the dot product engine 610.

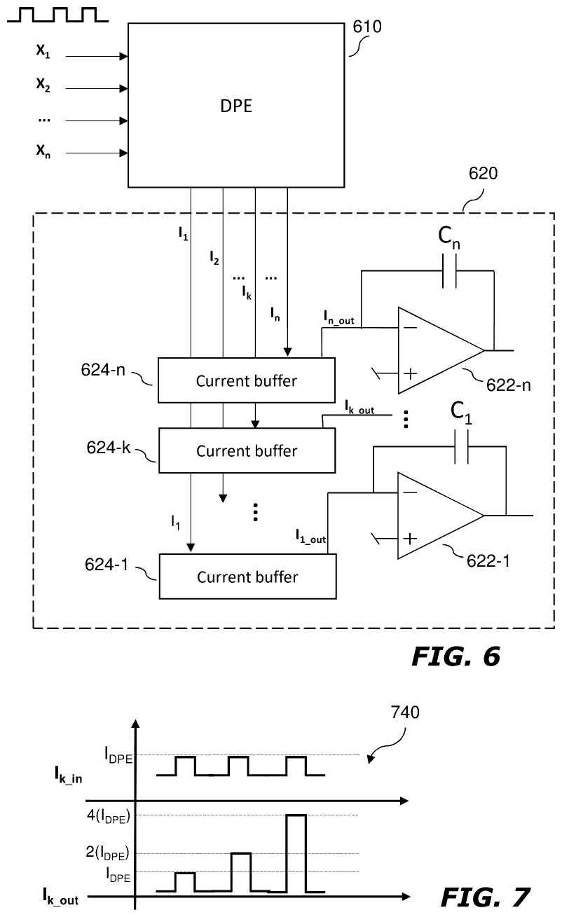

FIG. 7 illustrates a generalized timing diagram 740 for the operation of the example shown in FIG. 6. The top portion of the chart shows integration stage input current I_{DPE} received from the dot product engine 610. The current I_{DPE} has the same magnitude going into each current buffer 624, i.e., I₁=I₂=Iₙ (generalized as I_{k_in} in the chart). The amplitude of the current pulses may be modulated for each element in the sliced input vector by design of the mirror ratios within the different current buffers 624. In the example illustrated here, the output I_{k_out} of each current buffer 523-k is mirrored so that I_{k_out}=I_{DPE}·(2^{Nbitshift-1}), where N_{bitshift} represents a bit position of that current buffer. In other words, if k is the bit position, I_{k_out} is equal to I_{DPE}·(2^{k-1}), as shown in the figure. As illustrated in FIG. 7, the current mirror has a gain of 1 for the first pulse, 2 for the second pulse, and 4 for the third pulse.

FIG. 8 provides an example implementation similar to that of FIG. 6. This example uses a single integrator with an amplifier 822 and a capacitor C. The output values of the dot product engine 810 are encoded by the charge integrated by the integration circuit 820 and the division operation is performed with a current buffer that has a programmable mirroring ratio.

In this example, each column of the dot product engine 810 is fed to a current buffer 824, which conveys a summed signal towards the integrator 822, C. This summed signal is weighted by the mirroring factor. The mirroring factor may define the magnitude of the scalar value that is summed on the feedback capacitor of the integrator stage. This scalar value may be the result of a dot product between the input vector and a matrix column. The use of a single integrator with an amplifier 822 and a capacitor C in the dot product engine 810 may provide a more compact and efficient design.

In an alternate example implementation that is not shown, more than one integrator 822, C can be included. For example the most significant bits may be fed into a first integrator and the least significant bits into a second integrator. In fact, any number of integrators between 1 and n can be included in various implementations.

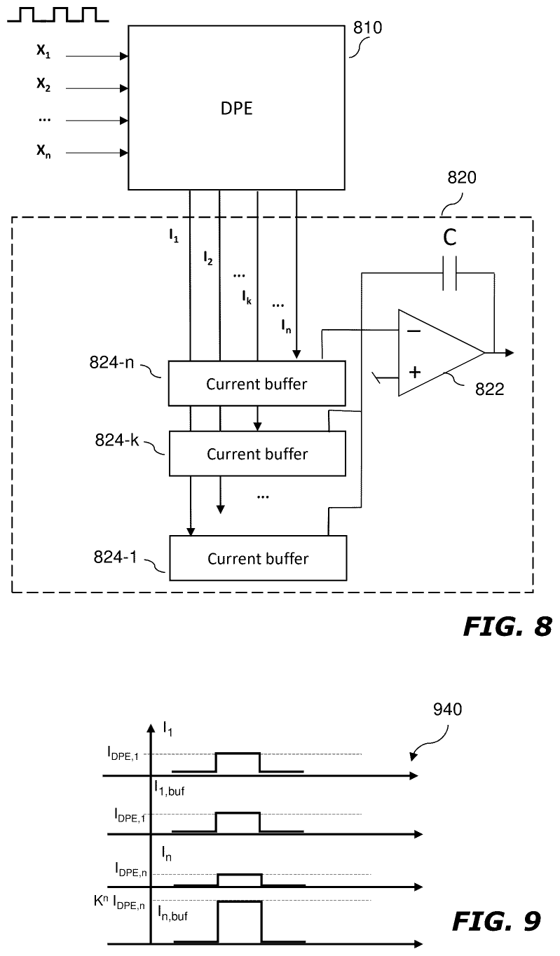

FIG. 9 illustrates a timing diagram 940 for the operation of the example shown in FIG. 8. In some aspects, the amplitude of the current pulses Iₖ may be modulated by the amplitude of each element in the sliced input vector as defined by the current mirror ratio. The chart shows two arbitrary examples, for the first current buffer 824-1 and the nth current buffer 824-n.

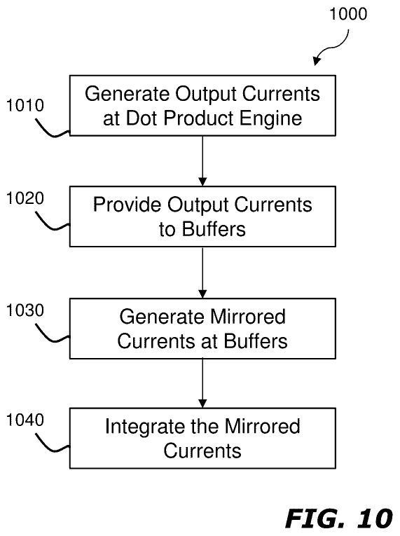

FIG. 10 illustrates an example implementation of a method of performing an analog computation. This method can be performed by the circuit of FIG. 6 or FIG. 8, as but two examples.

In operation 1010, a set of output currents is generated at a dot product engine. Each output current corresponds to dot product related to a respective input of the dot product engine. Each output current can then be provided to a respective current buffer in operation 1020. While not required, each current buffer can have a programmable mirroring ratio.

At each current buffer, a mirrored current is generated based a respective one of the output currents in operation 1030. A magnitude of each mirrored current is determined by a mirroring ratio at that current buffer. The mirroring ratio corresponds to a bit-significance of the respective one of the output currents. The mirrored currents can then be integrated using an integrator in operation 1040.

In an example implementation, the integrator comprises at least one amplifier with a feedback capacitor coupled between an input and an output of the amplifier. The integrator can be used to accumulate charge corresponding to the mirrored currents.

In an example implementation, integrator comprises a plurality of amplifiers, each having a feedback capacitor coupled between an input and an output of that amplifier. Each of the amplifiers is coupled to a different one of the current buffers.

In another example implementation, the integrator comprises a single amplifier and a single feedback capacitor where the mirrored currents from multiple current buffers are summed on the feedback capacitor.

In an example implementation, the dot product engine comprises a plurality of columns. Each column is configured to convey a summed signal towards the integrator. The summed signal is weighted by the mirroring factor of the current buffer associated with the respective column.

FIG. 11 illustrates an example of an implementation of any of the examples disclosed herein. In some aspects, inputs to the dot product engine 1110 may be provided by row drivers 1108. After the combination, the outputs of the dot product engine 1110 are be provided to an integration circuit 1120, here labeled as an analog shift and add circuit. The output of the integration circuit 1120 may be provided to an analog content addressable memory (ACAM) 1130.

An analog content addressable memory (ACAM) is a specialized type of memory that allows for efficient search and retrieval of data based on content rather than explicit addresses. In the system of FIG. 11, the ACAM 1130 receives analog data from a dot product engine 1110 via the integration circuit 1120. Advantageously, no analog-to-digital conversion is needed.

The ACAM 1130 operates by storing analog data patterns and their associated addresses or indices. When an analog input is presented, the ACAM performs a parallel search across all stored patterns to find the closest match. This parallel search capability makes ACAMs efficient for pattern recognition, data classification, and associative retrieval tasks, particularly in applications involving analog or continuous-valued data. ACAMs are particularly useful in applications like neural networks, signal processing, and pattern recognition, where the data is inherently analog or continuous-valued, and the computation involves complex operations like matrix multiplications and vector operations.

In an example implementation, input data, typically in the form of a vector, is fed into the dot product engine 1110 via the row drivers 1108. The dot product engine 1110 performs a matrix-vector multiplication between the input vector and the stored weight matrix thereby producing an analog output vector. This analog output vector is then integrated or summed by the integration circuit 1120, resulting in a single analog value or vector. This integrated analog value or vector is then presented to the ACAM 1130.

The ACAM 1130 compares the received analog value or vector with its stored content, which includes analog data patterns. If a match is found between the received analog data and one of the stored patterns in the ACAM 1130, the ACAM can return a signal indicating the presence of a match or it can output additional information affiliated with the stored analog pattern that corresponds to the input. For example, the ACAM 1130 can output a corresponding address or index of the matching pattern.

The example of FIG. 11 provides only a single example implementation. It will be understood that the embodiments disclosed herein can be used in a variety of implementations.

While this disclosure has been described with reference to illustrative implementations, this description is not intended to be construed in a limiting sense. Various modifications and combinations of the illustrative implementations, as well as other implementations of the disclosure, will be apparent to persons skilled in the art upon reference to the description. It is therefore intended that the appended claims encompass any such modifications or implementations.

What is claimed is:

1. A circuit comprising:
a dot product engine;
a plurality of integrators, wherein each integrator comprises:
an amplifier circuit having an input and an output, the input being coupled to an associated output of the dot product engine;
an integration capacitor selectively coupled between the input and output of the amplifier circuit;
a chop capacitor selectively coupled in parallel with the integration capacitor between the input and output of the amplifier circuit;
a first switch coupled between the input of the amplifier circuit and a first node of the integration capacitor;
a second switch coupled between the output of the amplifier and a second node of the integration capacitor;
a third switch coupled between the first node of the integration capacitor and a first node of the chop capacitor;
a fourth switch coupled between the second node of the integration capacitor and a second node of the chop capacitor; and
a fifth switch coupled between the first node of the chop capacitor and the second node of the chop capacitor.

2. The circuit of claim 1, wherein the integration capacitor and the chop capacitor are configured to share charge in a manner that corresponds to a bit shift operation.

3. The circuit of claim 1, wherein the first, second, and fifth switches are controllable to open and close at the same time and wherein the third and fourth switches are controllable to open and close at the same time.

4. The circuit of claim 1, wherein the chop capacitor of each integrator has a different capacitance value relative to capacitance values of the chop capacitors of each other integrator.

5. The circuit of claim 4, wherein the chop capacitor of each integrator is dimensioned according to formula C_{chop}=Cᵢₙₜ·(2^{Nbitshift}−1), where C_{chop} is a capacitance of the chop capacitor, Cᵢₙₜ is a capacitance of the integration capacitor, and N_{bitshift} represents a bit position of that integrator.

6. The circuit of claim 1, wherein the dot product engine comprises a memristor array.

7. The circuit of claim 1, further comprising a current buffer circuit coupled to the dot product engine.

8. A circuit comprising:
a dot product engine;
a buffer circuit comprising a plurality of current buffers, each current buffer having an input coupled to an associated output of the dot product engine; and
an integrator circuit coupled to receive outputs of the current buffers.

9. The circuit of claim 8, wherein the integrator circuit comprises an integrator having an input and an output, wherein the output of each current buffer is coupled to the input of the integrator.

10. The circuit of claim 8, wherein the integrator circuit comprises a plurality of integrators, wherein the output of each current buffer is coupled to an input of an associated one of the integrators.

11. The circuit of claim 8, wherein the buffer circuit has a mirroring ratio for dividing a current signal provided from the dot product engine by a fixed amount.

12. The circuit of claim 11, wherein the buffer circuit is configured to combine multiple currents for weight slicing.

13. A method comprising:
receiving input data at a dot product engine;
performing a dot product operation within the dot product engine; and
integrating charge output from the dot product engine using an integration capacitor and a chop capacitor, the integrating being performed by iteratively adding and dividing charge to accumulate a result corresponding to the dot product of the input data and matrix entries encoded in the dot product engine, the chop capacitor being reset for each iteration.

14. The method of claim 13, wherein integrating the charge comprises operating a set of switches connected to the integration capacitor and the chop capacitor, wherein the switches are controlled by control signals to implement charge sharing between the capacitors.

15. The method of claim 13, wherein integrating the charge comprises integrating the charge output from the dot product engine with a plurality of integrators each of which includes a respective integration capacitor and chop capacitor, the integration capacitor or chop capacitor of each integrator being weighted so that a result of the integrating corresponds to a bit shift operation.

16. A method comprising:
generating a set of output currents at a dot product engine, each output current corresponding to dot product related to a respective input of the dot product engine;
providing each output current to a respective current buffer;
at each current buffer, generating a mirrored current based a respective one of the output currents, wherein a magnitude of each mirrored current is determined by a mirroring ratio at that current buffer, the mirroring ratio corresponding to a bit-significance of the respective one of the output currents; and
integrating the mirrored currents using an integrator.

17. The method of claim 16, wherein the integrator comprises at least one amplifier with a feedback capacitor coupled between an input and an output of the amplifier, the integrator accumulating charge corresponding to the mirrored currents.

18. The method of claim 17, wherein the integrator comprises a plurality of amplifiers, each with a feedback capacitor coupled between an input and an output of that amplifier, wherein each of the amplifiers is coupled to a different one of the current buffers.

19. The method of claim 17, wherein the integrator comprises a single amplifier and a single feedback capacitor, and wherein the mirrored currents from multiple current buffers are summed on the feedback capacitor.

20. The method of claim 16, wherein the dot product engine comprises a plurality of columns, each column configured to convey a summed signal towards the integrator, and wherein the summed signal is weighted by a mirroring factor of the current buffer associated with the respective column.
